(19) United States
(12) Patent Application Publication
(10) Pub. No.: US 2026/0351308 A1
(43) Pub. Date: Nov. 5, 2026

(54) SRAM WRITE MARGIN VARIATION EXTRACTION STRUCTURE AND METHOD

(71) Applicant: Shanghai Huali Integrated Circuit Corporation, Shanghai (CN)

(72) Inventor: Pinhan CHEN, Shanghai (CN)

(21) Appl. No.: 19/464,260

(22) Filed: Jan. 29, 2026

(30) Foreign Application Priority Data
Apr. 30, 2025 (CN) 202510572419.2

(51) Int. Cl. G11C 11/419; G11C 29/54

(52) U.S. Cl. CPC G11C 11/419; G11C 29/54

(57) ABSTRACT

The present disclosure discloses an SRAM write margin variation extraction structure including a test array formed by arranging m*n SRAM cells. In each SRAM cell, a word line terminal, a power supply voltage terminal, and the unselected bit line terminal are connected together. In a test array, the power supply voltage terminals of all SRAM cells in the same row are connected to a power supply voltage line in the same row and connected to one test pad; the selected bit line terminals of all SRAM cells in the same column are connected to a bit line in the same column and connected to one test pad. All N-well pin-out terminals are connected together, all P-well pin-out terminals are connected together, all ground terminals are connected together; and all of them are respectively connected to one test pad. The present disclosure further discloses an SRAM write margin variation extraction method.

### CROSS-REFERENCES TO RELATED APPLICATIONS

This application claims priority to Chinese patent application No. 202510572419.2, filed on Apr. 30, 2025, the disclosure of which is incorporated herein by reference in its entirety.

### TECHNICAL FIELD

The present disclosure relates to a semiconductor integrated circuit manufacturing method, and particularly to a Static Random Access Memory (SRAM) write margin variation extraction structure. The present disclosure further relates to an SRAM write margin variation extraction method.

### BACKGROUND

In the past 20-30 years, with the rapid development of microelectronics technology, characterized by rapid device scaling, increased chip density, and high-speed computational performance, semiconductor memories have also been advancing significantly. Among volatile memories, SRAM is known for its low power consumption and high performance, while DRAM is characterized by low cost and large storage capacity.

Currently, in System on a Chip (SoC) designs, various memories are embedded to enhance system performance, particularly Static Random Access Memory (SRAM) circuits. Due to their compatibility with standard CMOS processes and common use as Level 1/Level 2 (L1/L2) cache in processing chips, SRAM naturally becomes the preferred choice for embedded memory. Therefore, SRAM holds a significant proportion in the functionality and application of digital chips.

The primary functional operations of SRAM are: write, read, and standby. The corresponding electrical performance metrics, evaluated during Wafer Acceptance Test (WAT), include write margin, noise margin, and standby leakage.

In SRAM write margin testing, a write operation is performed on the corresponding SRAM cell during circuit operation, and its write capability is quantitatively characterized. This is used to evaluate the read/write balance characteristic of the SRAM.

Please refer to FIG. 2A for a circuit diagram of an SRAM cell within an SRAM circuit. It includes pull-up transistors PU101 and PU102, pull-down transistors PD101 and PD102, pass gates PG101 and PG102, storage nodes n101 and n102, bit lines BL1 and BL2, a word line WL, a power supply voltage terminal Vdd, and a ground terminal Vss. Since the pull-up transistors PU101 and PU102 are formed in an N-well, there is also an N-well pin-out terminal NW. Similarly, since the pull-down transistors PD101 and PD102 are formed in a P-well, there is also a P-well pin-out terminal PW.

SRAM circuit write operation:

As shown in FIG. 2A, assuming initial internal signals are: the storage nodes n101 and n102 at 0V and 1V respectively, when a write operation is required, the following signals need to be applied:

WL=1V to turn on the pass gates, such that BL1 and BL2 are set to 1V and 0V respectively. This causes the signals at the storage nodes n101 and n102 to flip, thus completing the write operation. The storage nodes n101 and n102 change to 1V and 0V respectively.

The WAT SRAM write margin test quantifies the write capability of this SRAM.

The existing SRAM write margin test method includes the following steps:

First, a test structure (test key, TSK) is set up.

As described in FIG. 1, which shows a test pad arrangement of a test structure used in the existing SRAM write margin test method. First, the layout of an SRAM array and pin-out terminals, i.e., test pads 101, for connecting pins must be designed on the TSK. FIG. 1 shows that nine test pads 101 need to be arranged. These nine test pads correspond to the terminals shown in FIG. 2A: NW, PW, Vdd, Vss, BL1, BL2, WL, n101, n102. These 9 test pads can connect to pins, enabling test signals to be applied to various terminals of the SRAM cell.

Subsequently, a write margin test is performed, including:
1. As shown in FIG. 2A, first a write operation WL=1V is performed to turn on PG1 and PG2; BL1, BL2 are set to 0V and 1V respectively; the voltage states of n101 and n102 are monitored. The initial internal condition is: n101 and n102 at 0V and 1V respectively.
2. As shown in FIG. 2B, both BL1 and BL2 are set to 1V, WL=1V, that is, the voltage of BL1 is switched to 1V.
3. The voltage states of n101 and n102 are continuously monitored. In FIG. 2B, n101 and n102 remain unchanged, i.e., at 0V and 1V respectively.
4. As shown in FIG. 2C, WL=1V (ON) and BL1=1V are set, and BL2 sweeps from 1V (high level) to 0V (low level).
5. When the states of n101, n102 flip, i.e., n101 and n102 become 1V and 0V respectively, it indicates the write operation is complete. The voltage of BL2 at this point is the write margin voltage.

As shown in FIG. 3, which shows voltage change curves of storage nodes during the BL2 voltage sweep in the existing SRAM write margin test method, where curve 102 represents the voltage curve of the storage node n102, and curve 103 represents the voltage curve of the storage node n101. Flip points of n101 and n102 can be identified from curves 102 and 103, and the corresponding voltage of BL2 at this point is the write margin voltage.

The existing SRAM write margin test method has the following disadvantages:
1. The TSK layout requires numerous pin pads, i.e., test pads, consuming significant area.
2. The tester needs to provide a large number of Source Measurement Unit (SMU) ports. Each SMU port needs to support both output and input.
3. The test program (PGM) is relatively complex.

The above describes the measurement of the write margin for a single SRAM cell. When extracting the SRAM write margin variation, a large amount of data needs to be measured, meaning measurements must be performed on a large number of SRAM cells to obtain numerous write margin values. This is necessary to determine and analyze the write margin variation, which in turn allows analysis of the intrinsic characteristics of SRAM read/write operations, process stability, and improvement of SRAM/chip yield.

In the existing SRAM write margin variation extraction method, it is necessary to create the TSK shown in FIG. 1 for each SRAM cell. Each TSK requires nine pin-out pads. Repeating this array structure is needed to obtain a sufficient amount of write margin data to calculate its standard deviation, i.e., the write margin variation.

Consequently, obtaining a large amount of write margin data requires considerable resources, layout area, and test time.

### BRIEF SUMMARY

According to some embodiments in this application, an SRAM write margin variation extraction structure disclosed in this application comprising:a test array formed by arranging m*n SRAM cells, where m is greater than or equal to 1, n is greater than or equal to 1, and m*n is greater than or equal to 2.

Connecting terminals of each SRAM cell include a word line terminal, a power supply voltage terminal, a ground terminal, an N-well pin-out terminal, a P-well pin-out terminal, a first bit line terminal, and a second bit line terminal; any one of the first bit line terminal and the second bit line terminal is a selected bit line terminal, the other is an unselected bit line terminal, and the word line terminal, the power supply voltage terminal, and the unselected bit line terminal are connected together.

The test array includes at least m+n+3 test pads.

In the test array, the power supply voltage terminals of all SRAM cells in the same row are connected to a power supply voltage line in the same row, the power supply voltage line is led out through a corresponding test pad, the selected bit line terminals of all SRAM cells in the same column are connected to a bit line in the same column, and the bit line is led out through a corresponding test pad.

The N-well pin-out terminals of all SRAM cells are connected together and led out through a corresponding test pad;

the P-well pin-out terminals of all SRAM cells are connected together and led out through a corresponding test pad;

the ground terminals of all SRAM cells are connected together and led out through a corresponding test pad.

In some case,the SRAM cell includes a first inverter and a second inverter, an output terminal of the first inverter and an input terminal of the second inverter are connected to a first storage node, and an output terminal of the second inverter and an input terminal of the first inverter are connected to a second storage node.

In some case,a first source/drain of a first pass gate composed of an NMOS transistor is connected to the first bit line terminal, a second source/drain is connected to the first storage node, and a gate is connected to the word line terminal;

a first source/drain of a second pass gate composed of an NMOS transistor is connected to the second bit line terminal, a second source/drain is connected to the second storage node, and a gate is connected to the word line terminal.

In some case,the first inverter includes a first pull-up transistor composed of a PMOS transistor and a first pull-down transistor composed of an NMOS transistor;

a source of the first pull-up transistor is connected to the power supply voltage terminal, a drain of the first pull-down transistor and a drain of the first pull-up transistor are connected to the first storage node, a source of the first pull-down transistor is connected to the ground terminal, and a gate of the first pull-up transistor and a gate of the first pull-down transistor are connected to the second storage node.

In some case,the second inverter includes a second pull-up transistor composed of a PMOS transistor and a second pull-down transistor composed of an NMOS transistor;

a source of the second pull-up transistor is connected to the power supply voltage terminal, a drain of the second pull-down transistor and a drain of the second pull-up transistor are connected to the second storage node, a source of the second pull-down transistor is connected to the ground terminal, and a gate of the second pull-up transistor and a gate of the second pull-down transistor are connected to the first storage node.

In some case,m is equal to 8, n is equal to 8, and the number of the test pads is 22.

In order to solve the technical problem, the SRAM write margin variation extraction method provided in the present disclosure includes the following steps:
step 1: applying 1V to the test pad shared by all N-well pin-out terminals, applying 0V to the test pad shared by all P-well pin-out terminals, and applying 0V to the test pad shared by all ground terminals;
step 2: extracting a write margin of the selected SRAM cell, allowing the selected SRAM cell to be located in an ith row and a jth column (1 ≤ i ≤ m, 1 ≤ j ≤ n), including the following sub-steps: step
2a: applying a voltage of 1V to the bit line in the jth column;
step 2b: applying a voltage of 0V to the power supply voltage line in the ith row, then switching the voltage of the power supply voltage line in the ith row to 1V, then measuring the current of the bit line in the jth column, and completing writing of a first state signal in the selected SRAM cell when it is detected that the current of the bit line in the jth column is 0A; and
step 2c: sweeping the voltage of the bit line in the jth column from 1V to 0V, and simultaneously monitoring the current of the bit line in the jth column, where when the monitored current of the bit line in the jth column suddenly jumps from a negative value to a positive value, it indicates that a stored signal in the selected SRAM cell has switched from the first state signal to an inverted second state signal, and the corresponding voltage of the bit line in the jth column is the write margin at this point;
step 3: changing the values of i and j, and then repeating step 2 until the write margins of all SRAM cells in the test array are obtained; and
step 4: obtaining an SRAM write margin variation value based on the obtained write margins of all SRAM cells in the test array.

In some case,the SRAM cell includes a first inverter and a second inverter, an output terminal of the first inverter and an input terminal of the second inverter are connected to a first storage node, and an output terminal of the second inverter and an input terminal of the first inverter are connected to a second storage node.

In some case,a first source/drain of a first pass gate composed of an NMOS transistor is connected to the first bit line terminal, a second source/drain is connected to the first storage node, and a gate is connected to the word line terminal;

a first source/drain of a second pass gate composed of an NMOS transistor is connected to the second bit line terminal, a second source/drain is connected to the second storage node, and a gate is connected to the word line terminal.

In some case,the first inverter includes a first pull-up transistor composed of a PMOS transistor and a first pull-down transistor composed of an NMOS transistor;

a source of the first pull-up transistor is connected to the power supply voltage terminal, a drain of the first pull-down transistor and a drain of the first pull-up transistor are connected to the first storage node, a source of the first pull-down transistor is connected to the ground terminal, and a gate of the first pull-up transistor and a gate of the first pull-down transistor are connected to the second storage node.

In some case,the second inverter includes a second pull-up transistor composed of a PMOS transistor and a second pull-down transistor composed of an NMOS transistor;

a source of the second pull-up transistor is connected to the power supply voltage terminal, a drain of the second pull-down transistor and a drain of the second pull-up transistor are connected to the second storage node, a source of the second pull-down transistor is connected to the ground terminal, and a gate of the second pull-up transistor and a gate of the second pull-down transistor are connected to the first storage node.

In some case,m is equal to 8, n is equal to 8, and the number of the test pads is 22.

In some case,the initial value of i is 1, and the initial value of j is 1; in step 3, when the values of i and j are changed each time, only one of i and j is incremented by 1, while the other is either kept unchanged or reset to the initial value.

In some case,in step 3, the logic for changing the values of i and j each time is as follows:
when i < m, j remains unchanged and i is incremented by 1; and
when i = m, if j < n, then j is incremented by 1 and i is set to 1, and if j = n, then step 3 is stopped.

Through the arrangement of the test array, the present disclosure can obtain multiple SRAM cells for testing write margins, SRAM cells in the same row can share a power supply voltage line and a test pad, SRAM cells in the same column can share a bit line and a test pad, the word line terminal and the unselected bit line terminal of each SRAM cell are both connected to the power supply voltage terminal, the N-well pin-out terminals of all SRAM cells are connected together and share a test pad, the P-well pin-out terminals of all SRAM cells are connected together and share a test pad, the ground terminals of all SRAM cells are connected together and share a test pad, and the storage nodes of each SRAM cell do not need to be led out or have corresponding test pads, thus reducing the number of test pads, reducing the layout area of the extraction structure, and finally reducing the chip area.

In addition, the SRAM cells and test array adopted in the present disclosure can be implemented merely by configuring the layout of photomasks, specifically by configuring only the layout of metal interconnects. Consequently, the present disclosure does not require additional photomasks and will not increase the cost.

The present disclosure does not require any changes to the intrinsic structure of the SRAM cells. Therefore, the manufacturing steps for the SRAM cells remain unchanged. Based on the modified photomask layout, subsequent metal interconnect processes also do not incur additional steps or complexity. Therefore, the present disclosure avoids adding process steps and the associated complexity.

By arranging the test array, the present disclosure enables the acquisition of a large amount of data, i.e., the write margins of the SRAM cells, through testing. The more SRAM cells included in the test array, the more data can be acquired, and the higher the precision of the obtained SRAM write margin variation value. Therefore, by arranging the test array, the present disclosure can improve the test precision of the SRAM write margin variation value.

In the present disclosure, during testing, after applying fixed voltages to the N-well pin-out terminal, P-well pin-out terminal, and ground terminal, it only requires applying corresponding voltages to the bit line and power supply voltage line of the selected SRAM cell and measuring the current of the bit line to collect the write margin of each SRAM cell. The present disclosure does not require measuring the voltages of the storage nodes. Therefore, the present disclosure can also reduce the number of Source Measurement Units (SMUs) required by the tester, simplify the test program, and increase the test speed. Since the test speed for each individual SRAM cell is increased, combined with the test array, the total time required to complete the SRAM write margin variation testing in the present disclosure can be significantly reduced. Therefore, the present disclosure can also reduce the test time.

### BRIEF DESCRIPTION OF THE DRAWINGS

The present disclosure will be further described below in detail in combination with the specific embodiments with reference to the drawings.

FIG. 1 shows an arrangement diagram of a test pad of a test structure adopted in an existing SRAM write margin test method.

FIGS. 2A-2C show circuit diagrams of operations on an SRAM cell during an existing SRAM write margin test method.

FIG. 3 shows voltage change curves of storage nodes during BL2 voltage sweeping in an existing SRAM write margin test method.

FIG. 4 shows a circuit diagram of a test array of an SRAM write margin variation extraction structure according to an embodiment of the present disclosure.

FIG. 5 shows an arrangement diagram of a test pad of an SRAM write margin variation extraction structure according to an embodiment of the present disclosure.

FIG. 6A shows a simplified circuit diagram of an SRAM cell of an SRAM write margin variation extraction structure when a first bit line terminal is a selected bit line terminal according to an embodiment of the present disclosure.

FIG. 6B shows a circuit diagram of an SRAM cell of an SRAM write margin variation extraction structure when a first bit line terminal is a selected bit line terminal according to an embodiment of the present disclosure.

FIG. 7A shows a simplified circuit diagram of an SRAM cell of an SRAM write margin variation extraction structure when a second bit line terminal is a selected bit line terminal according to an embodiment of the present disclosure.

FIG. 7B shows a circuit diagram of an SRAM cell of an SRAM write margin variation extraction structure when a second bit line terminal is a selected bit line terminal according to an embodiment of the present disclosure.

FIG. 8A shows a diagram of a layout below a first metal layer of an SRAM cell of an SRAM write margin variation extraction structure according to an embodiment of the present disclosure.

FIG. 8B shows a diagram of a layout below a first via layer of an SRAM cell of an SRAM write margin variation extraction structure according to an embodiment of the present disclosure.

FIG. 8C shows a diagram of a layout below a second metal layer of an SRAM cell of an SRAM write margin variation extraction structure according to an embodiment of the present disclosure.

FIG. 8D shows a diagram of a layout below a second via layer of an SRAM cell of an SRAM write margin variation extraction structure according to an embodiment of the present disclosure.

FIG. 8E shows a diagram of a layout below a third metal layer of an SRAM cell of an SRAM write margin variation extraction structure according to an embodiment of the present disclosure.

FIGS. 9A-9C show circuit diagrams of operations on a selected SRAM cell in an SRAM write margin variation extraction method according to an embodiment of the present disclosure.

FIG. 10 shows change curves of BLa and BLb currents during BLb voltage sweeping on a selected SRAM cell in an SRAM write margin variation extraction method according to an embodiment of the present disclosure.

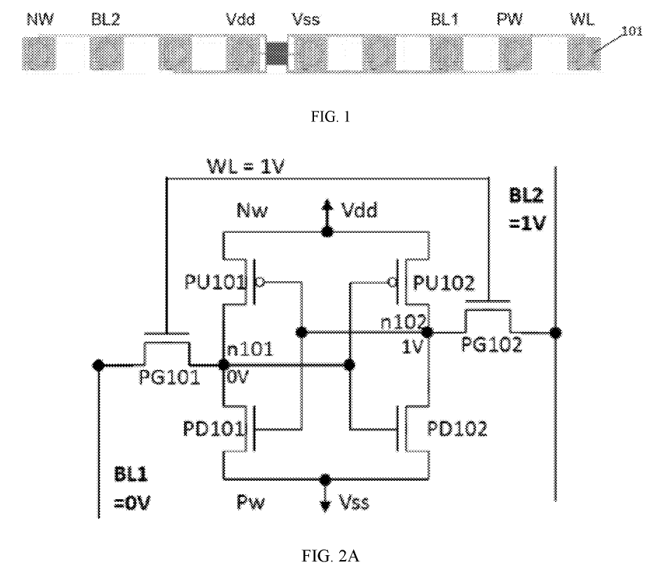

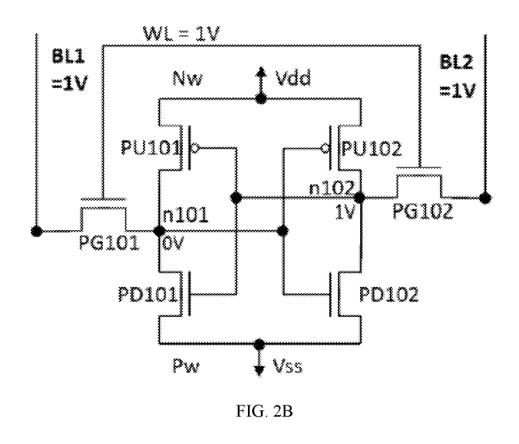

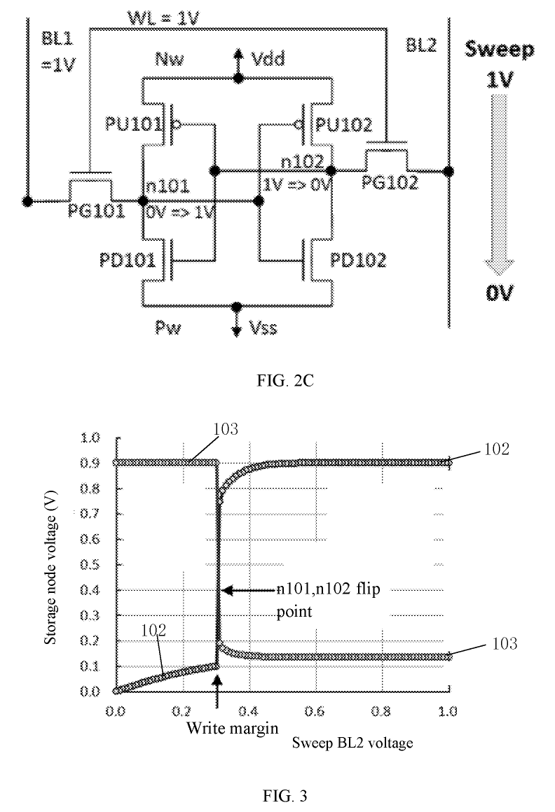

### DETAILED DESCRIPTION OF THE EMBODIMENTS

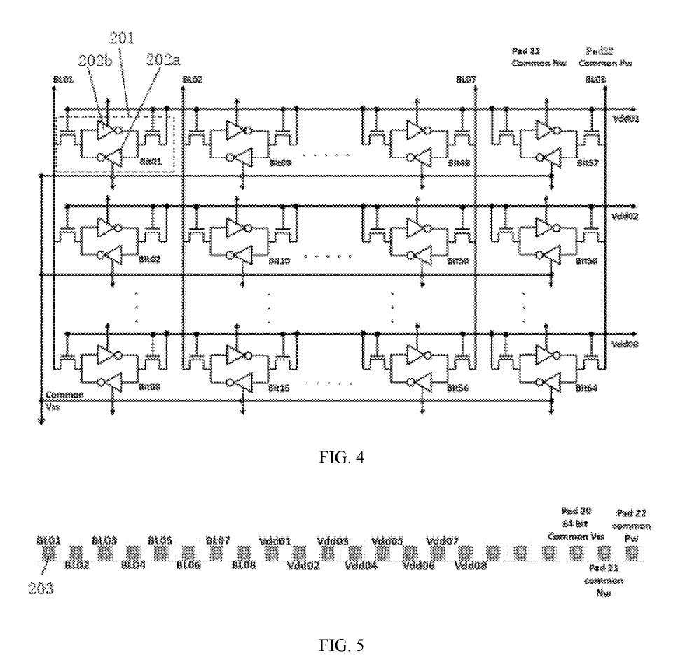

As shown in FIG. 4, which shows a circuit diagram of a test array of an SRAM write margin variation extraction structure according to an embodiment of the present disclosure, the SRAM write margin variation extraction structure according to an embodiment of the present disclosure includes a test array formed by arranging m*n SRAM cells 201, where m is greater than or equal to 1, n is greater than or equal to 1, and m*n is greater than or equal to 2.

In an example corresponding to FIG. 4, m and n are both equal to 8, resulting in a total of 64 SRAM cells 201. In FIG. 4, the 64 SRAM cells 201 are respectively labeled as Bit01, Bit02, ..., Bit64.

In other embodiments, the values of m and n may be set as needed. For example, they can be set based on the required test precision. If the required test precision is not high, the values of m and n may be decreased; conversely, if the required test precision is high, the values of m and n may be increased.

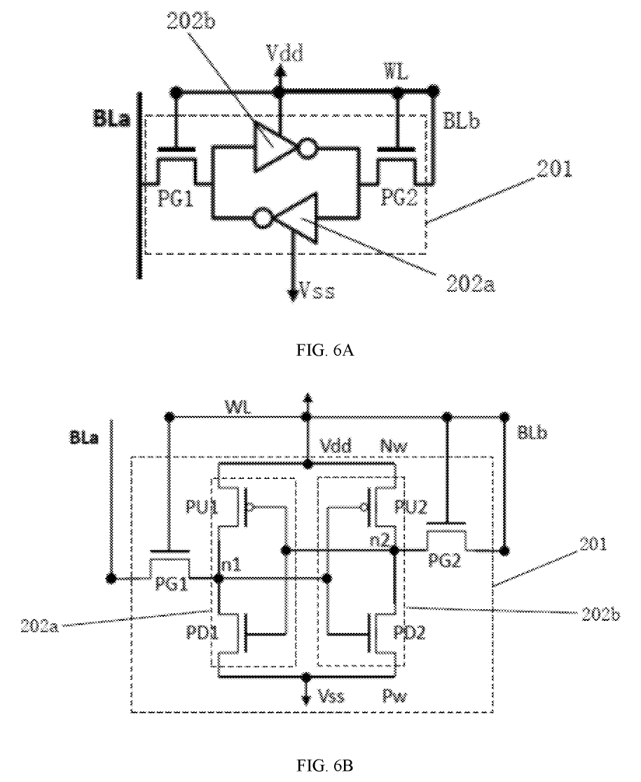

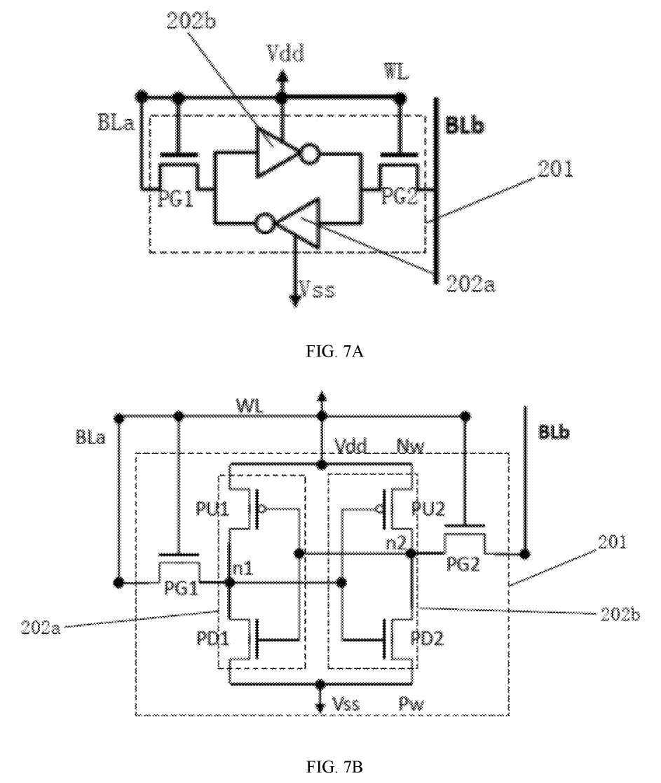

As shown in FIG. 6A, which shows a simplified circuit diagram of an SRAM cell 201 when a first bit line terminal BLa is a selected bit line terminal according to an embodiment of the present disclosure. As shown in FIG. 7A, which shows a simplified circuit diagram of an SRAM cell 201 when a second bit line terminal BLb is a selected bit line terminal according to an embodiment of the present disclosure. Connecting terminals of each SRAM cell 201 include a word line terminal WL, a power supply voltage terminal Vdd, a ground terminal Vss, an N-well pin-out terminal NW, a P-well pin-out terminal PW, a first bit line terminal BLa, and a second bit line terminal BLb. Any one of the first bit line terminal BLa and the second bit line terminal BLb is a selected bit line terminal, and the other is an unselected bit line terminal. The word line terminal WL, the power supply voltage terminal Vdd, and the unselected bit line terminal are connected together. In FIG. 6A, since the first bit line terminal BLa is the selected bit line terminal, the second bit line terminal BLb is the unselected bit line terminal. Therefore, the word line terminal WL, the power supply voltage terminal Vdd, and the second bit line terminal BLb are connected together. In FIG. 7A, since the second bit line terminal BLb is the selected bit line terminal, the first bit line terminal BLa is the unselected bit line terminal. Therefore, the word line terminal WL, the power supply voltage terminal Vdd, and the first bit line terminal BLa are connected together.

In this embodiment of the present disclosure, the test array not only can adopt the connecting structure of the SRAM cell 201 shown in FIG. 6A, as shown by the SRAM cell corresponding to Bit01 in FIG. 4, but also can adopt the connecting structure of the SRAM cell 201 shown in FIG. 7A, as shown by the SRAM cell corresponding to Bit49 in FIG. 4.

As shown in FIG. 5, which shows a layout diagram of a test pads 203 of an SRAM write margin variation extraction structure according to an embodiment of the present disclosure, the test array includes at least m+n+3 test pads 203. The number of the test pads 203 in FIG. 5 is set according to the test array in the example of FIG. 4. FIG. 5 includes a total of 22 test pads 203.

Jointly referring to FIG. 4, in the test array, the power supply voltage terminals Vdd of all SRAM cells 201 in the same row are connected to a power supply voltage line in the same row, and the power supply voltage line is led out through a corresponding test pad 203. In FIG. 4, the power supply voltage lines are denoted using Vdd+row number, e.g., Vdd01 represents the power supply voltage line in a first row. FIG. 4 shows eight rows of such power supply voltage lines, i.e., Vdd01, Vdd02, ..., Vdd08.

The selected bit line terminals of all SRAM cells 201 in the same column are connected to a bit line in the same column, and the bit line is led out through a corresponding test pad 203. In FIG. 4, the bit lines are denoted using BL+column number, e.g., BL01 represents the bit line in a first column. FIG. 4 shows eight rows of such bit lines, i.e., BL01, BL02, ..., BL08.

The N-well pin-out terminals NW of all SRAM cells 201 are connected together and led out through a corresponding test pad 203. In FIG. 4, the N-well pin-out terminals NW of all SRAM cells 201 are connected to a common N-well terminal, and the common N-well terminal is also denoted as Common NW in FIG. 4. In FIG. 5, the common N-well terminal is connected to a 21st test pad 203, and the 21st test pad 203 is also denoted as Pad 21 in FIG. 5. Pad 21 is also shown in FIG. 4.

The P-well pin-out terminals PW of all SRAM cells 201 are connected together and led out through a corresponding test pad 203. In FIG. 4, the P-well pin-out terminals PW of all SRAM cells 201 are connected to a common P-well terminal. The common P-well terminal is also denoted as Common PW in FIG. 4. In FIG. 5, the common P-well terminal is connected to a 22nd test pad 203. The 22nd test pad 203 is also denoted as Pad 22 in FIG. 5. Pad 22 is also shown in FIG. 4.

The ground terminals Vss of all SRAM cells 201 are connected together and led out through a corresponding test pad 203. In FIG. 4, the ground terminals Vss of all SRAM cells 201 are connected to a common ground terminal. The common ground terminal is also denoted as Common Vss in FIG. 4. In FIG. 5, the common ground terminal is connected to a 20th test pad 203. The 20th test pad 203 is also denoted as Pad 20 in FIG. 5.

As shown in FIG. 6A, the SRAM cell 201 includes a first inverter 202a and a second inverter 202b, an output terminal of the first inverter 202a and an input terminal of the second inverter 202b are connected to a first storage node n1, and an output terminal of the second inverter 202b and an input terminal of the first inverter 202a are connected to a second storage node n2.

A first source/drain of a first pass gate PG1 composed of an NMOS transistor is connected to the first bit line terminal BLa, a second source/drain is connected to the first storage node n1, and a gate is connected to the word line terminal WL.

A first source/drain of a second pass gate PG2 composed of an NMOS transistor is connected to the second bit line terminal BLb, a second source/drain is connected to the second storage node n2, and a gate is connected to the word line terminal WL.

As shown in FIG. 6B, which is a circuit diagram of an SRAM cell 201 when a first bit line terminal BLa is a selected bit line terminal according to an embodiment of the present disclosure; the first inverter 202a includes a first pull-up transistor PU1 composed of a PMOS transistor and a first pull-down transistor PD1 composed of an NMOS transistor.

A source of the first pull-up transistor PU1 is connected to the power supply voltage terminal Vdd, a drain of the first pull-down transistor PD1 and a drain of the first pull-up transistor PU1 are connected to the first storage node n1, a source of the first pull-down transistor PD1 is connected to the ground terminal Vss, and a gate of the first pull-up transistor PU1 and a gate of the first pull-down transistor PD1 are connected to the second storage node n2.

The second inverter 202b includes a second pull-up transistor PU2 composed of a PMOS transistor and a second pull-down transistor PD2 composed of an NMOS transistor.

A source of the second pull-up transistor PU2 is connected to the power supply voltage terminal Vdd, a drain of the second pull-down transistor PD2 and a drain of the second pull-up transistor PU2 are connected to the second storage node n2, a source of the second pull-down transistor PD2 is connected to the ground terminal Vss, and a gate of the second pull-up transistor PU2 and a gate of the second pull-down transistor PD2 are connected to the first storage node n1.

Through the arrangement of the test array, the present disclosure can obtain multiple SRAM cells 201 for testing write margins, SRAM cells 201 in the same row can share a power supply voltage line and a test pad 203, SRAM cells 201 in the same column can share a bit line and a test pad 203, the word line terminal WL and the unselected bit line terminal of each SRAM cell 201 are both connected to the power supply voltage terminal Vdd, the N-well pin-out terminals NW of all SRAM cells 201 are connected together and share a test pad 203, the P-well pin-out terminals PW of all SRAM cells 201 are connected together and share a test pad 203, the ground terminals Vss of all SRAM cells 201 are connected together and share a test pad 203, and the storage nodes of each SRAM cell 201 do not need to be led out or have corresponding test pads 203, thus reducing the number of test pads 203, reducing the layout area of the extraction structure, and finally reducing the chip area.

In addition, the SRAM cells 201 and test array adopted in this embodiment of the present disclosure can be implemented merely by configuring the layout of photomasks, specifically by configuring only the layout of metal interconnects. Therefore, the present disclosure does not require additional photomasks and will not increase the cost.

This embodiment of the present disclosure does not require any changes to the intrinsic structure of the SRAM cells 201. Therefore, the manufacturing steps for the SRAM cells 201 remain unchanged. Based on the modified photomask layout, subsequent metal interconnect processes also do not incur additional steps or complexity. Therefore, the present disclosure avoids adding process steps and the associated complexity.

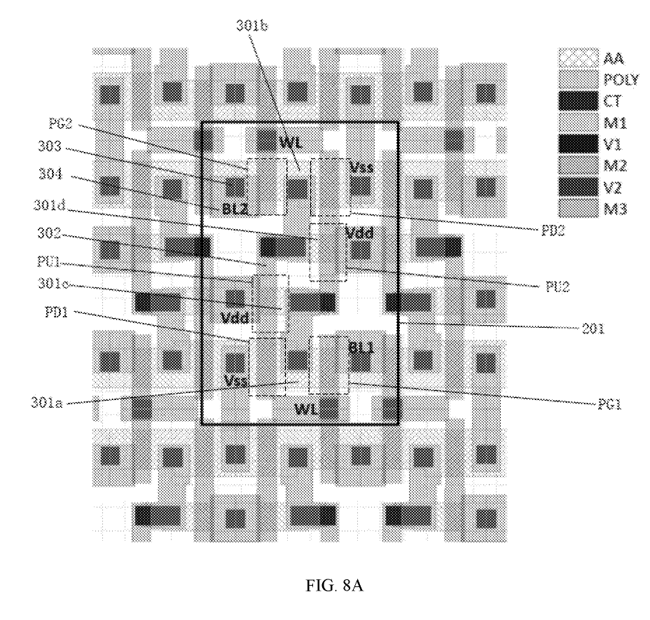

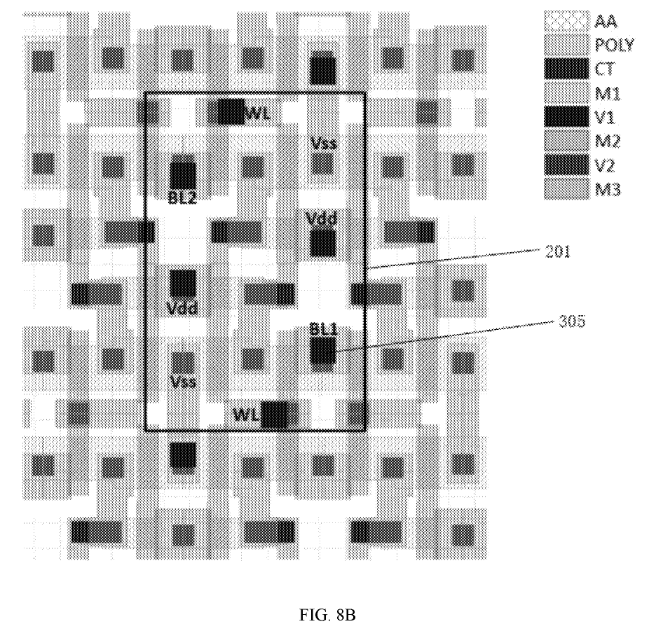

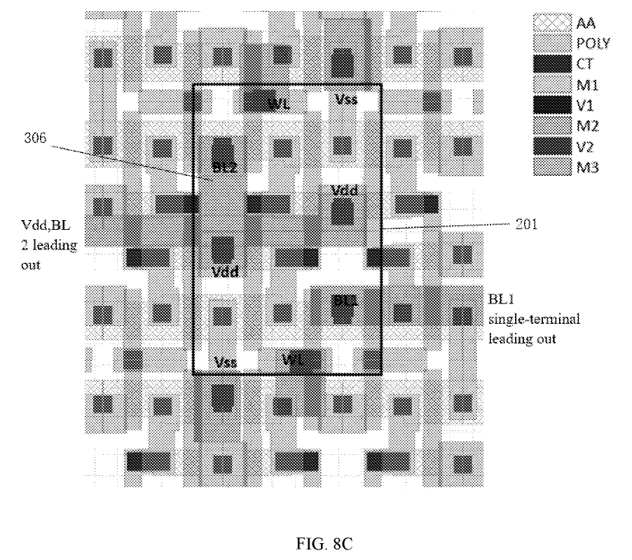

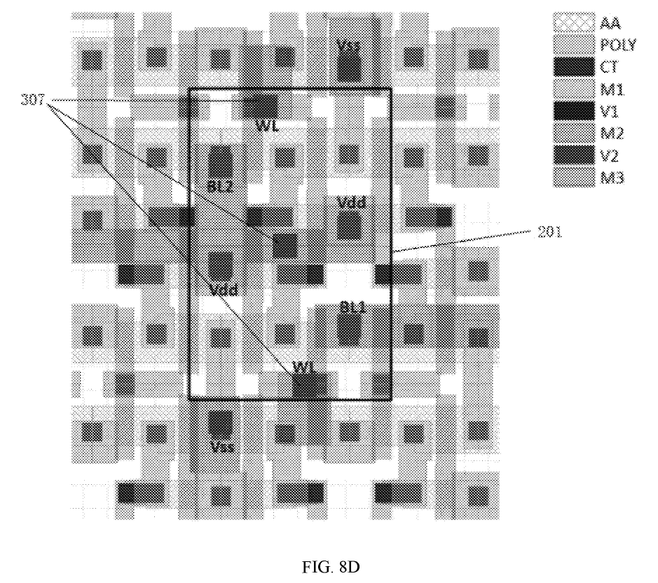

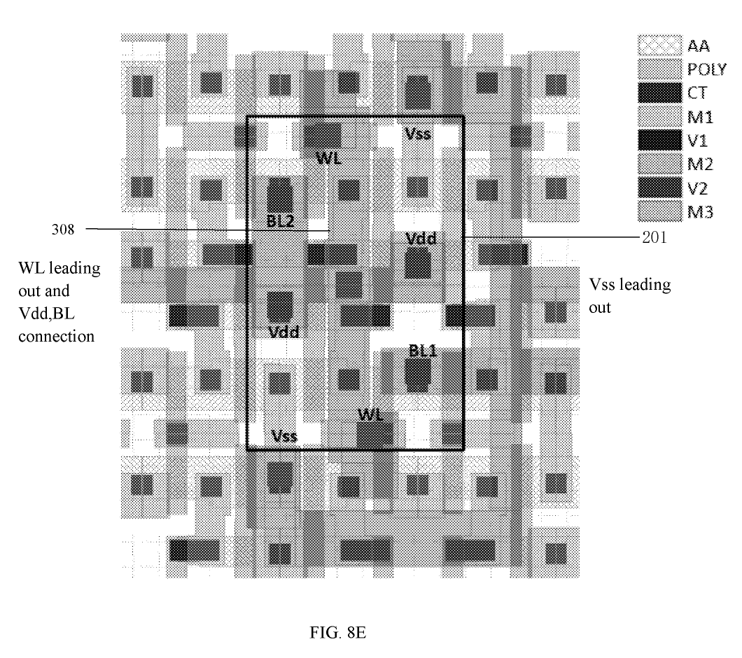

As shown in FIG. 8A, it shows a diagram of a layout below a first metal layer of an SRAM cell of an SRAM write margin variation extraction structure according to an embodiment of the present disclosure. In this embodiment, the layout below the first metal layer may be identical to the conventional structure. The SRAM cell 201 includes four active areas (AA), where a first active area 301a is shared by the first pull-down transistor PD1 and the first pass gate PG1; a second active area 301b is shared by the second pull-down transistor PD2 and the second pass gate PG2; a third active area 301c is used for forming the first pull-up transistor PU1; and a fourth active area 301d is used for forming the second pull-up transistor PU2. P-wells are formed in both the first active area 301a and the second active area 301b, while N-wells are formed in both the third active area 301c and the fourth active area 301d.

The gate structures of all transistors, i.e., PG1, PG2, PD1, PD2, PU1, and PU2, are composed of polysilicon strips 302 crossing over corresponding active areas. PU1 and PD1 share the same polysilicon strip 302, and PU2 and PD2 share the same polysilicon strip 302.

Source and drain regions of each transistor are formed in the active areas on two sides of the corresponding polysilicon strip 302.

The source/drain regions and gate structures of each transistor are connected to the corresponding first metal layer (M1) 304 via contacts (CT) 303 formed on the top to form the corresponding electrode terminals. For example, the first source/drain of PG2 is connected to the bit line terminal BL2 formed by the first metal layer 304 via a contact 303 on the top. In FIG. 8A, the bit line terminal BL2 is the second bit line terminal BLb shown in FIG. 6B. The contact 303 on the top of the source of PD2 is connected to the ground terminal Vss formed by the first metal layer 304. The second source/drain of PG2 and the drain of PD2 are shared and connected to the first metal layer 304 corresponding to the second storage node n2 via the corresponding contact 303 on the top. The polysilicon strip 302 shared by PU1 and PD1 is also connected to the first metal layer 304 corresponding to the second storage node n2 via a corresponding contact 303 on the top.

The top of the source of PU2 is connected to the power supply voltage terminal Vdd formed by the first metal layer 304 via the contact 303. The top of the drain of PU2 is connected to the first metal layer 304 corresponding to the second storage node n2 via the contact 303.

The polysilicon strip 302 of PG2 is connected to the word line terminal WL formed by the first metal layer 304 via the corresponding contact 303 on the top.

Similarly, the first source/drain of PG1 is connected to the bit line terminal BL1 formed by the first metal layer 304 via the contact 303 on the top. In FIG. 8A, the bit line terminal BL1 is the first bit line terminal BLa shown in FIG. 6B. The contact 303 on the top of the source of PD1 is connected to the ground terminal Vss formed by the first metal layer 304. The second source/drain of PG1 and the drain of PD1 are shared and connected to the first metal layer 304 corresponding to the first storage node n1 via the corresponding contact 303 on the top. The polysilicon strip 302 shared by PU2 and PD2 is also connected to the first metal layer 304 corresponding to the first storage node n1 via a corresponding contact 303 on the top.

The top of the source of PU1 is connected to the power supply voltage terminal Vdd formed by the first metal layer 304 via the contact 303. The top of the drain of PU1 is connected to the first metal layer 304 corresponding to the first storage node n1 via the contact 303.

The polysilicon strip 302 of PG1 is connected to the word line terminal WL formed by the first metal layer 304 via the corresponding contact 303 on the top.

FIG. 8A also shows patterns corresponding to each layer, where AA represents an active area pattern, POLY represents a polysilicon strip 302 pattern, CT represents a contact 303 pattern, and M1 represents a first metal layer 304 pattern. FIG. 8A also shows patterns of layers added in subsequent FIGS. 8B-8E, where V1 representing a first via layer pattern, M2 representing a second metal layer pattern, V2 representing a second via layer pattern, and M3 representing a third metal layer pattern.

As shown in FIG. 8B, it shows a diagram of a layout below a first via layer (V1) of an SRAM cell of an SRAM write margin variation extraction structure according to an embodiment of the present disclosure. FIG. 8B is a diagram of a layout after adding a first via layer based on FIG. 8A. As can be seen from FIG. 8B, in the SRAM cell 201, a first via 305 is respectively arranged on the tops of the bit line terminals BL1 and BL2, the two word line terminals WL, and the two power supply voltage terminals Vdd. The first metal layer 304 pattern corresponding to the two ground terminals Vss extend outside the SRAM cell 201. Corresponding first vias 305 are also formed on the top of the first metal layer 304 pattern corresponding to the ground terminals Vss that extend outside the SRAM cell 201.

As shown in FIG. 8C, it shows a diagram of a layout below a second metal layer of an SRAM cell of an SRAM write margin variation extraction structure according to an embodiment of the present disclosure. FIG. 8C is a diagram of a layout after adding a second metal layer 306 based on FIG. 8B. As can be seen from FIG. 8C, the bit line terminal BL2 and the two power supply voltage terminals Vdd are respectively connected to the same second metal layer 306 pattern through the first vias 305 on the top to lead out BL2 and Vdd; the bit line terminal BL1 is connected to the corresponding second metal layer 306 pattern through the first via 305 on the top to lead out a single terminal of BL1.

Corresponding second metal layer 306 patterns are also formed on the top of the first vias 305 corresponding to the word line terminals WL and the ground terminals Vss.

As shown in FIG. 8D, it shows a diagram of a layout below a second via (V2) layer of an SRAM cell of an SRAM write margin variation extraction structure according to an embodiment of the present disclosure. FIG. 8D is a diagram of a layout after adding a second via layer based on FIG. 8C. As can be seen from FIG. 8D, in the SRAM cell 201, a second via 307 is respectively formed on the top of the second metal layer 306 patterns corresponding to the bit line terminal BL2 and the two word line terminals WL; outside the SRAM cell 201, a second via 307 is respectively formed on the top of the second metal layer 306 patterns corresponding to the two ground terminals Vss.

As shown in FIG. 8E, it shows a diagram of a layout below a third metal layer of an SRAM cell of an SRAM write margin variation extraction structure according to an embodiment of the present disclosure. FIG. 8E is a diagram of a layout after adding a third metal layer 308 based on FIG. 8C. As can be seen from FIG. 8E, the second metal layer 306 corresponding to the bit line terminal BL2 and the second metal layer 306 corresponding to the two word line terminals WL are respectively connected to the same third metal layer 308 pattern through the second vias 307 on the top to lead out the word line terminals WL and connect to Vdd and BL2.

The second vias 307 on the top of the second metal layer 306 patterns corresponding to the two ground terminals Vss are connected to the same third metal layer 308 pattern to lead out the ground terminals Vss.

As can be seen from FIGS. 8A-8E, in this embodiment of the present disclosure, it is only necessary to configure the layout patterns for each photomask layer, and no additional photomasks are required, thus reducing the cost.

By arranging the test array, this embodiment of the present disclosure enables the acquisition of a large amount of data, i.e., the write margins of the SRAM cells 201, through testing. The more SRAM cells 201 included in the test array, the more data can be acquired, and the higher the precision of the obtained SRAM write margin variation value. Therefore, by arranging the test array, this embodiment of the present disclosure can improve the test precision of the SRAM write margin variation value.

From the above, it can be seen that in this embodiment of the present disclosure, based on a test key with 22 pads, a measurable architecture with a total of 8*8=64 bits can be designed, enabling the measurement of the electrical characteristics of 64 write margins.

Using a single SRAM cell (i.e., bit) as the unit, the write margins corresponding to the 64 bits (Bit 01 to Bit 64) can be used to calculate the write margin variation.

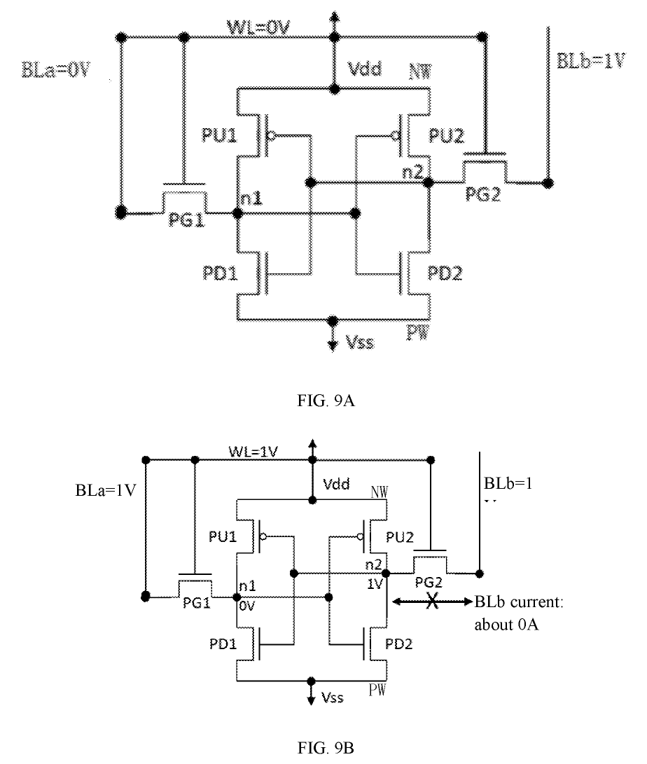

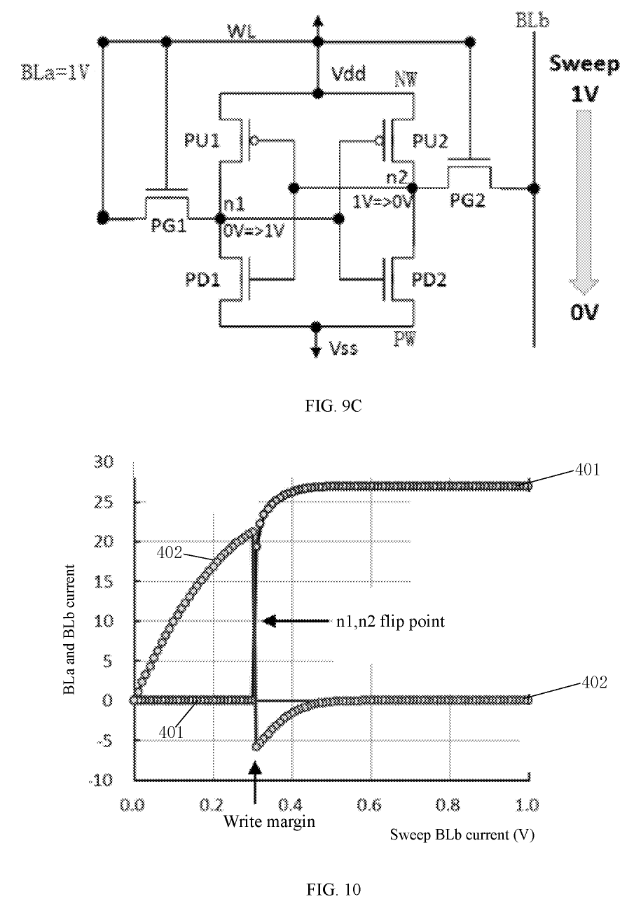

As shown in FIGS. 9A-9C, they show circuit diagrams of operations on a selected SRAM cell in an SRAM write margin variation extraction method according to an embodiment of the present disclosure. By taking an SRAM write margin variation extraction method using the previously described SRAM write margin variation extraction structure according to the embodiment of the present disclosure as an example, the SRAM write margin variation extraction method according to this embodiment of the present disclosure includes the following steps:

In step 1, 1V is applied to the test pad 203 shared by all N-well pin-out terminals NW, 0V is applied to the test pad 203 shared by all P-well pin-out terminals PW, and 0V is applied to the test pad 203 shared by all ground terminals Vss. That is, 1V is applied to Pad 21, 0V is applied to Pad 22, and 0V is applied to Pad 20 in FIG. 5.

In step 2, a write margin of the selected SRAM cell 201 is extracted. Allowing the selected SRAM cell 201 is allowed to be located in an ith row and a jth column (1 ≤ i ≤ m, 1 ≤ j ≤ n), it includes the following sub-steps:

In step 2a, a voltage of 1V is applied to the bit line in the jth column.

In FIG. 9A, the selected SRAM cell 201 has the same connecting structure as the SRAM cell 201 shown in FIG. 7B. In other examples, the selected SRAM cell 201 may also have the same connecting structure as the SRAM cell 201 shown in FIG. 6B.

The bit line in the jth column is connected to the second bit line terminal BLb of the selected SRAM cell 201. Therefore, a voltage of 1V is applied to the second bit line terminal BLb of the selected SRAM cell 201.

In step 2b, a voltage of 0V is applied to the power supply voltage line in the ith row.

As shown in FIG. 9A, the power supply voltage line in the ith row is connected to the first bit line terminal BLa, the power supply voltage terminal Vdd, and the word line terminal WL of the selected SRAM cell 201. Therefore, applying 0V to the power supply voltage line in the ith row means applying 0V to the power supply voltage terminal Vdd of the selected SRAM cell 201.

Then, the voltage of the power supply voltage line in the ith row is switched to 1V. As shown in FIG. 9B, this means the voltage of the power supply voltage terminal Vdd of the selected SRAM cell 201 is switched to 1V.

Then, the current of the bit line in the jth column is measured, and writing of a first state signal in the selected SRAM cell 201 is completed when it is detected that the current of the bit line in the jth column is 0A. In FIG. 9B, measuring the current of the bit line in the jth column means testing the current of the second bit line terminal BLb of the selected SRAM cell 201. After the second storage node n2 rises to 1V, the second pass gate PG2 turns off, and the current of the second bit line terminal BLb becomes approximately 0A. At this point, the writing of the first state signal is completed. This first state signal corresponds to the first storage node n1 being at 0V, i.e., low level, and the second storage node n2 being at 1V, i.e., high level.

In step 2c, the voltage of the bit line in the jth column is swept from 1V to 0V, and simultaneously the current of the bit line in the jth column is monitored, where when the monitored current of the bit line in the jth column suddenly jumps from a negative value to a positive value, it indicates that a stored signal in the selected SRAM cell 201 has switched from the first state signal to an inverted second state signal, and the corresponding voltage of the bit line in the jth column is the write margin at this point.

In FIG. 9C, "Sweep from 1V to 0V" indicates that the voltage of the second bit line terminal BLb of the selected SRAM cell 201 is swept from 1V to 0V.

While sweeping the voltage of the second bit line terminal BLb, the current of the second bit line terminal BLb is simultaneously measured. If the current of the second bit line terminal BLb suddenly jumps from a negative value to a positive value, the corresponding voltage of the second bit line terminal BLb is the write margin at this point.

As shown in FIG. 10, it shows change curves of BLa and BLb currents during BLb voltage sweeping on a selected SRAM cell in an SRAM write margin variation extraction method according to an embodiment of the present disclosure. Curve 401 is a curve of the current of BLa, and curve 402 is a curve of the current of BLb.

Hereafter, BLb directly denotes the second bit line terminal. The sweep voltage of BLb will decrease from 1V to 0V. As shown in FIG. 10, when the voltage of BLb is relatively high, the second storage node n2 remains stable at 1V, the second pass gate PG2 remains off, and thus the current of BLb is 0A. In addition, since the first storage node n1 is at 0V, the first pass gate PG1 is on, so the current of the first bit line maintains a relatively high value. This corresponds to an interval in FIG. 10 where the voltage of BLb is above 0.45V.

As the voltage of BLb decreases, for example, to 0.45V, the second pass gate PG2 gradually turns on, but the second storage node n2 still remains at 1V. At this point, the current of BLb flows from the power supply terminal Vdd, through the second pull-up transistor PU2, the second storage node n2, and the second pass gate PG2, to BLb. This corresponds to an interval in FIG. 10 where the voltage of BLb is between 0.45V and 0.3V.

When the voltage of BLb continues to decrease, for example, to 0.3V, the first storage node n1 and the second storage node n2 flip. At this point, the voltage of the second storage node n2 becomes 0V, and the voltage of the first storage node n1 becomes 1V. Consequently, the current of BLb flows from BLb, through the second pass gate PG2, the second storage node n2, and the second pull-down transistor PD2, to the ground terminal Vss. Therefore, the direction of the current of BLb reverses. At this point, the first pass gate PG2 turns off, so the current of the first bit line becomes 0A.

When the voltage of BLb continues to drop, for example, to 0V, the current of BLb further decreases, which corresponds to an interval in FIG. 10 where the voltage of BLb is between 0.25V and 0V.

In step 3, the values of i and j are changed, and then step 2 is repeated until the write margins of all SRAM cells 201 in the test array are obtained.

In step 4, an SRAM write margin variation value is obtained based on the obtained write margins of all SRAM cells 201 in the test array.

In some embodiments, the initial value of i is 1 and the initial value of j is 1; step 2 is first performed with i=1 and j=1, after which step 3 is performed.

In step 3, when the values of i and j are changed each time, only one of i and j is incremented by 1, while the other is either kept unchanged or reset to the initial value. In step 3, the logic for changing the values of i and j each time is as follows:
when i < m, j remains unchanged and i is incremented by 1; and
when i = m, if j < n, then j is incremented by 1 and i is set to 1, and if j = n, then step 3 is stopped.

In other embodiments, other logic for changing the values of i and j may also be adopted, provided that after repeatedly performing step 2 multiple times, all the SRAM cells 201 in the test array can be completely tested.

In some examples of the method according to this embodiment of the present disclosure, a test process includes:
firstly setting common terminals Vss=0V, Pw=0V, Nw=1V;
testing Bit01:
step S1: setting BL01=1V;
step S2: setting Vdd01=0V, then setting Vdd01=1V, and monitoring whether the current of BL01 approximates 0A, which represents that the initial condition has been written;
step S3: sweeping BL01 from 1V to 0V, where when the current of BL01 suddenly jumps from low to high (changing from negative to positive), it means that the writing has been completed, and the voltage of BL01 at this point is Bit01 write margin voltage;
testing Bit02, repeating steps S1, S2, and S3 to obtain Bit02 write margin voltage;
testing Bit03, repeating steps S1, S2, and S3 to obtain Bit03 write margin voltage;
continuously repeating steps S1, S2, and S3, until testing 64, repeating steps S1, S2, and S3 to obtain Bit64 write margin voltage.

Using the data, i.e., 64 write margin voltages, the SRAM write margin variation (standard deviation) can be obtained, which can be used for calculating and analyzing the SRAM performance, evaluating the yield, and also observing the process stability.

In the method according to this embodiment of the present disclosure, during testing, after applying fixed voltages to the N-well pin-out terminal NW, P-well pin-out terminal PW, and ground terminal Vss, it only requires applying corresponding voltages to the bit line and power supply voltage line of the selected SRAM cell 201 and measuring the current of the bit line to collect the write margin of each SRAM cell 201. The method according to this embodiment of the present disclosure does not require measuring the voltages of the storage nodes. Therefore, the method according to this embodiment of the present disclosure can also reduce the number of SMUs required by the tester, simplify the test program, and increase the test speed. Since the test speed for each individual SRAM cell 201 is increased, combined with the test array, the total time required to complete the SRAM write margin variation testing in the method according to this embodiment of the present disclosure can be significantly reduced. Therefore, this embodiment of the present disclosure can also reduce the test time.

The present disclosure has been described above in detail through specific embodiments, which, however, do not constitute limitations to the present disclosure. Without departing from the principle of the present disclosure, those skilled in the art can also make many modifications and improvements, which should also be considered as included in the scope of protection of the present disclosure.

What is claimed is:

1. An SRAM write margin variation extraction structure, comprising a test array formed by arranging m*n SRAM cells, where m is greater than or equal to 1, n is greater than or equal to 1, and m*n is greater than or equal to 2, wherein
connecting terminals of each SRAM cell comprise a word line terminal, a power supply voltage terminal, a ground terminal, an N-well pin-out terminal, a P-well pin-out terminal, a first bit line terminal, and a second bit line terminal; any one of the first bit line terminal and the second bit line terminal is a selected bit line terminal, the other is an unselected bit line terminal, and the word line terminal, the power supply voltage terminal, and the unselected bit line terminal is connected together;
the test array comprises at least m+n+3 test pads;
in the test array, the power supply voltage terminals of all SRAM cells in the same row is connected to a power supply voltage line in the same row, the power supply voltage line is led out through a corresponding test pad, the selected bit line terminals of all SRAM cells in the same column are connected to a bit line in the same column, and the bit line is led out through a corresponding test pad;
the N-well pin-out terminals of all SRAM cells are connected together and led out through a corresponding test pad;
the P-well pin-out terminals of all SRAM cells are connected together and led out through a corresponding test pad;
the ground terminals of all SRAM cells are connected together and led out through a corresponding test pad.

2. The SRAM write margin variation extraction structure according to claim 1, wherein the SRAM cell comprises a first inverter and a second inverter, an output terminal of the first inverter and an input terminal of the second inverter are connected to a first storage node, and an output terminal of the second inverter and an input terminal of the first inverter are connected to a second storage node.

3. The SRAM write margin variation extraction structure according to claim 2, wherein a first source/drain of a first pass gate composed of an NMOS transistor is connected to the first bit line terminal, a second source/drain is connected to the first storage node, and a gate is connected to the word line terminal;
a first source/drain of a second pass gate composed of an NMOS transistor is connected to the second bit line terminal, a second source/drain is connected to the second storage node, and a gate is connected to the word line terminal.

4. The SRAM write margin variation extraction structure according to claim 3, wherein the first inverter comprises a first pull-up transistor composed of a PMOS transistor and a first pull-down transistor composed of an NMOS transistor;
a source of the first pull-up transistor is connected to the power supply voltage terminal, a drain of the first pull-down transistor and a drain of the first pull-up transistor are connected to the first storage node, a source of the first pull-down transistor is connected to the ground terminal, and a gate of the first pull-up transistor and a gate of the first pull-down transistor are connected to the second storage node.

5. The SRAM write margin variation extraction structure according to claim 4, wherein the second inverter comprises a second pull-up transistor composed of a PMOS transistor and a second pull-down transistor composed of an NMOS transistor;
a source of the second pull-up transistor is connected to the power supply voltage terminal, a drain of the second pull-down transistor and a drain of the second pull-up transistor are connected to the second storage node, a source of the second pull-down transistor is connected to the ground terminal, and a gate of the second pull-up transistor and a gate of the second pull-down transistor are connected to the first storage node.

6. The SRAM write margin variation extraction structure according to claim 1, wherein m is equal to 8, n is equal to 8, and the number of the test pads is 22.

7. An SRAM write margin variation extraction method using the SRAM write margin variation extraction structure according to claim 1, comprising the following steps:
step 1: applying 1V to the test pad shared by all N-well pin-out terminals, applying 0V to the test pad shared by all P-well pin-out terminals, and applying 0V to the test pad shared by all ground terminals;
step 2: extracting a write margin of the selected SRAM cell, allowing the selected SRAM cell to be located in an ith row and a jth column (1 ≤ i ≤ m, 1 ≤ j ≤ n), comprising the following sub-steps:
step 2a: applying a voltage of 1V to the bit line in the jth column;
step 2b: applying a voltage of 0V to the power supply voltage line in the ith row, then switching the voltage of the power supply voltage line in the ith row to 1V, then measuring the current of the bit line in the jth column, and completing writing of a first state signal in the selected SRAM cell when it is detected that the current of the bit line in the jth column is 0A; and
step 2c: sweeping the voltage of the bit line in the jth column from 1V to 0V, and simultaneously monitoring the current of the bit line in the jth column, wherein when the monitored current of the bit line in the jth column suddenly jumps from a negative value to a positive value, it indicates that a stored signal in the selected SRAM cell has switched from the first state signal to an inverted second state signal, and the corresponding voltage of the bit line in the jth column is the write margin at this point;
step 3: changing the values of i and j, and then repeating step 2 until the write margins of all SRAM cells in the test array are obtained; and
step 4: obtaining an SRAM write margin variation value based on the obtained write margins of all SRAM cells in the test array.

8. The SRAM write margin variation extraction method according to claim 7, wherein the SRAM cell comprises a first inverter and a second inverter, an output terminal of the first inverter and an input terminal of the second inverter are connected to a first storage node, and an output terminal of the second inverter and an input terminal of the first inverter are connected to a second storage node.

9. The SRAM write margin variation extraction method according to claim 8, wherein a first source/drain of a first pass gate composed of an NMOS transistor is connected to the first bit line terminal, a second source/drain is connected to the first storage node, and a gate is connected to the word line terminal;
a first source/drain of a second pass gate composed of an NMOS transistor is connected to the second bit line terminal, a second source/drain is connected to the second storage node, and a gate is connected to the word line terminal.

10. The SRAM write margin variation extraction method according to claim 9, wherein the first inverter comprises a first pull-up transistor composed of a PMOS transistor and a first pull-down transistor composed of an NMOS transistor;
a source of the first pull-up transistor is connected to the power supply voltage terminal, a drain of the first pull-down transistor and a drain of the first pull-up transistor are connected to the first storage node, a source of the first pull-down transistor is connected to the ground terminal, and a gate of the first pull-up transistor and a gate of the first pull-down transistor are connected to the second storage node.

11. The SRAM write margin variation extraction method according to claim 10, wherein the second inverter comprises a second pull-up transistor composed of a PMOS transistor and a second pull-down transistor composed of an NMOS transistor;
a source of the second pull-up transistor is connected to the power supply voltage terminal, a drain of the second pull-down transistor and a drain of the second pull-up transistor are connected to the second storage node, a source of the second pull-down transistor is connected to the ground terminal, and a gate of the second pull-up transistor and a gate of the second pull-down transistor are connected to the first storage node.

12. The SRAM write margin variation extraction method according to claim 7, wherein m is equal to 8, n is equal to 8, and the number of the test pads is 22.

13. The SRAM write margin variation extraction method according to claim 7, wherein the initial value of i is 1, and the initial value of j is 1; in step 3, when the values of i and j are changed each time, only one of i and j is incremented by 1, while the other is either kept unchanged or reset to the initial value.

14. The SRAM write margin variation extraction method according to claim 13, wherein in step 3, the logic for changing the values of i and j each time is as follows:
when i < m, j remains unchanged and i is incremented by 1; and
when i = m, if j < n, then j is incremented by 1 and i is set to 1, and if j = n, then step 3 is stopped.
